(19) United States
(12) Patent Application Publication
(10) Pub. No.: US 2014/0203360 A1
(43) Pub. Date: Jul. 24, 2014

(54) REDUCING CONTACT RESISTANCE BY DIRECT SELF-ASSEMBLING

(71) Applicant: INTERNATIONAL BUSINESS MACHINES CORPORATION, Armonk, NY (US)

(72) Inventors: Qing Cao, Yorktown Heights, NY (US); Kangguo Cheng, Schenectady, NY (US); Zhengwen Li, Scarsdale, NY (US); Fei Liu, Yorktown Heights, NY (US); Zhen Zhang, Ossining, NY (US)

(73) Assignee: INTERNATIONAL BUSINESS MACHINES CORPORATION, Armonk, NY (US)

(21) Appl. No.: 13/744,845

(22) Filed: Jan. 18, 2013

(51) Int. Cl. H01L 29/417; H01L 29/40

(52) U.S. Cl. CPC H01L 29/41766; H01L 29/401
USPC 257/347; 438/151

(57) ABSTRACT

As stated above, methods of forming a source/drain contact for a transistor are disclosed. In one embodiment, a transistor is formed on a semiconductor-on-insulator (SOI) substrate, which includes a semiconductor-on-insulator (SOI) layer, a buried insulator layer and a silicon substrate. This forming can include forming a gate and a source/drain region. A hardmask can then be formed over the transistor and a self-assembling (DSA) polymer can be directed to cover a portion of the source/drain region. A set of trenches can be formed through the hardmask and into the source/drain region using the DSA polymer as a mask. Then the polymer and the hardmask can be stripped, leaving the trenched source/drain region.

### BACKGROUND

1. Technical Field

The disclosure relates generally to integrated circuit (IC) chip fabrication, and more particularly, to methods of forming a contact to a source/drain region.

2. Background Art

In the field of integrated circuit technology, technology can change rapidly. In part, these changes result from a desire to maximize the utilization of available space. This can drive a push to miniaturize the components found on an integrated circuit. However, miniaturization of components can introduce scaling problems as miniaturized components can behave differently and, in some cases less efficiently, than their larger counterparts.

One type of integrated circuit in current use is a complementary metal-oxide-semiconductor (CMOS). FIG. 1 shows an example cross-section 10 of a CMOS. As shown, cross-section 10 includes a substrate 12 onto which a number of gates 14 have been formed. In the areas 20 between the gates 14 on the substrate have been formed a source/drain region (RSD) 22 with an associated silicide 24. Also shown in this area 20 are a number of spacers 16, which can be formed to separate the gates 14 from the RSD 22 and silicide 24. As shown, cross-section 10 has a pitch 30. This pitch 30 is a measurement of the amount of space occupied by one gate 14 and the area 20 between the gate 14 and an adjacent gate 14. To this extent, pitch 30 can be expressed as the sum of the space occupied by the gate 14, plus two of the spacers 16, plus the width of the RSD 32.

### SUMMARY

Applicants have discovered that as the pitch 30 for an integrated circuit decreases due to increased miniaturization, the area of the RSD 22 often decreases as well. This decrease in RSD 22 area can reduce the area that is used to connect the portion of the integrated circuit with a contact. The decreased contact area can increase the contact resistance between the contact and the RSD 22, and degrade performance.

Methods of forming a source/drain contact for a transistor are disclosed. In one embodiment, a transistor is formed on a semiconductor-on-insulator (SOI) substrate, which includes a semiconductor-on-insulator (SOI) layer, a buried insulator layer and a silicon substrate. This forming can include forming a gate and a source/drain region. A hardmask can then be formed over the transistor and a self-assembling (DSA) polymer can be directed to cover a portion of the source/drain region. A set of trenches can be formed through the hardmask and into the source/drain region using the DSA polymer as a mask. Then the polymer and the hardmask can be stripped, leaving the trenched source/drain region.

A first aspect of the disclosure provides a method of forming a contact area for an transistor, the method comprising: forming a transistor on a semiconductor-on-insulator (SOI) substrate, the forming including forming a gate and a source/drain region, the SOI substrate including a semiconductor-on-insulator (SOI) layer, a buried insulator layer and a silicon substrate; forming a hardmask over the integrated circuit; directing a self-assembling (DSA) polymer to cover a portion of the source/drain region; forming trenches through the hardmask and into the source/drain region using the DSA polymer as a mask; and stripping the polymer, and the hardmask.

A second aspect of the disclosure provides a transistor comprising: a gate; a source/drain region having series of channels therein; and a contact to the source/drain region that extends into the series of channels.

A third aspect of the disclosure provides a method of forming a contact to a transistor, the method comprising: forming a transistor on a semiconductor layer positioned over an etch stop layer positioned over a silicon substrate, the forming including forming a gate and a source/drain region; depositing a hardmask over the integrated circuit; applying a block mask perpendicular to the gate; directing a self-assembling (DSA) polymer to cover a portion of the source/drain region in alignment with the block mask; etching through hardmask and a portion of the source/drain region using the DSA polymer as a mask to form a series of trenches in the source/drain region; stripping the polymer, the block mask; and the hardmask; and forming a thin silicide contact layer over the source/drain region the silicide layer maintaining the series of trenches.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows an embodiment of a CMOS transistor.

FIG. 2 shows an embodiment of forming a transistor on an SOI substrate.

FIGS. 3A-C show depositing a hardmask over the transistor according to an embodiment.

FIGS. 4A-B show applying a block mask according to an embodiment.

FIGS. 5A-B shows directing a self-assembling polymer according to an embodiment.

FIG. 6 shows forming trenches into the source/drain region according to an embodiment.

FIGS. 7A-B show stripping masks according to an embodiment.

FIGS. 8A-B show stripping masks according to an embodiment.

FIGS. 9A-B show forming a contact according to an embodiment.

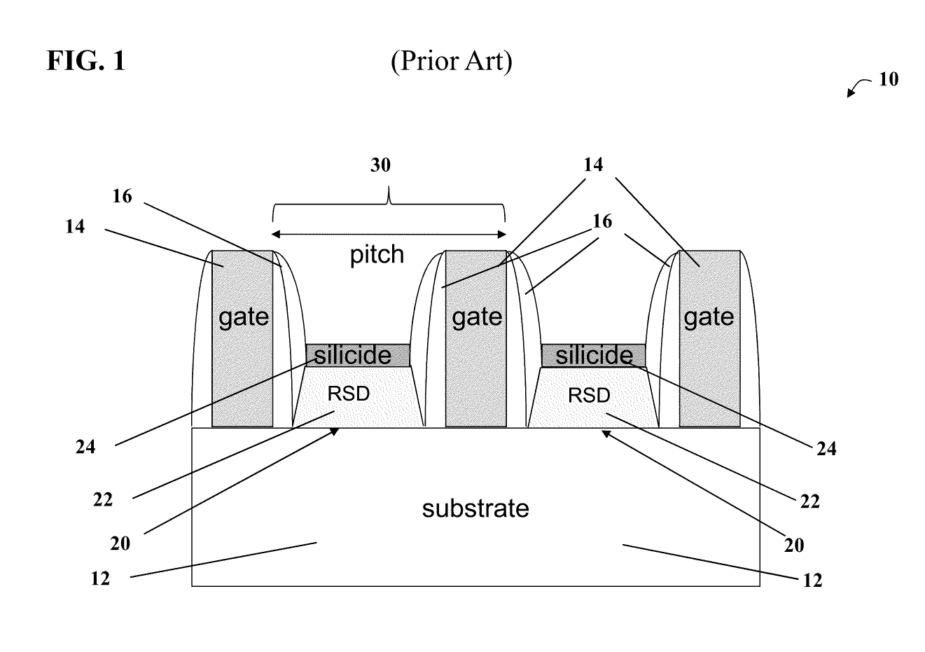

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As stated above, methods of forming a source/drain contact for a transistor are disclosed. In one embodiment, a transistor is formed on a semiconductor-on-insulator (SOI) substrate, which includes a semiconductor-on-insulator (SOI) layer, a buried insulator layer and a silicon substrate. This forming can include forming a gate and a source/drain region. A hardmask can then be formed over the transistor and a self-assembling (DSA) polymer can be directed to cover a portion of the source/drain region. A set of trenches can be formed through the hardmask and into the source/drain region using the DSA polymer as a mask. Then the polymer and the hardmask can be stripped, leaving the trenched source/drain region.

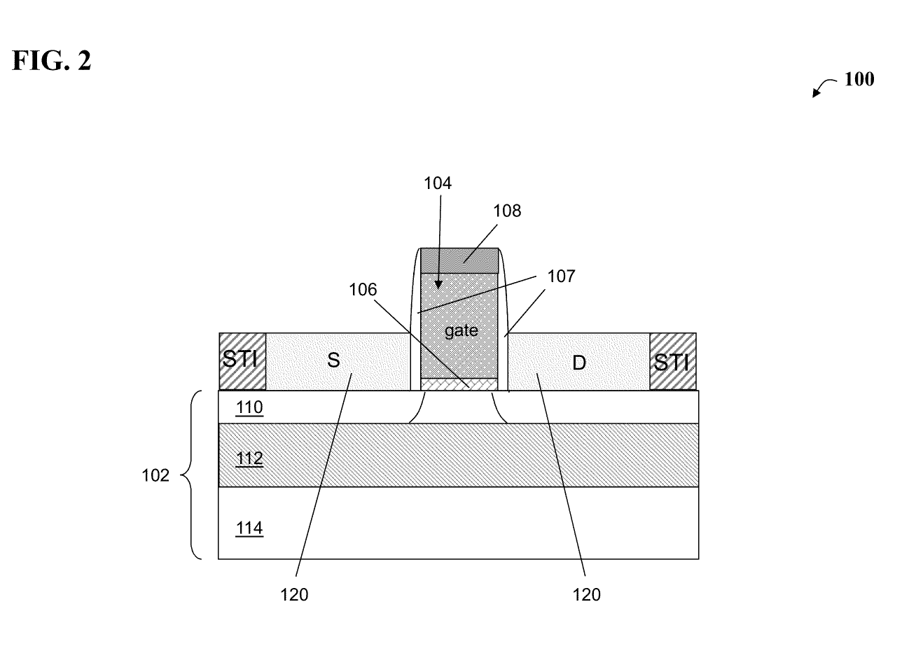

Turning to the drawings, FIG. 2 shows an embodiment of forming a transistor 100 on a semiconductor-on-insulator (SOI) substrate 102. As illustrated, the forming includes forming a gate 104 with an accompanying gate dielectric 106, spacers 107, gate hardmask 108, and a source/drain region 120. As shown in FIG. 2, transistor 100 forming may also include forming an isolation region (not shown) for transistor 100A-C. Isolation region (not shown) can be formed between transistors to provide isolation and to define the transistor widths as necessary. The formation of this isolation region typically involves etching away regions of SOI layer 110, refilling with an insulator (e.g., SiO₂), and planarizing. Electrical contacts to the gates can be formed in places where the gate is over an isolation region. Gate 104 may include any now known or later developed gate polysilicon or gate metal. SOI substrate 102 includes a semiconductor-on-insulator (SOI) layer 110, a buried insulator layer 112 and a silicon substrate 114.

In an alternative embodiment, rather than using an SOI substrate 102, the teachings of the application may be applied where buried insulator layer 112 is replaced with an etch stop layer 112 (same location) selective to substrate 114. Etch stop layer 112 may include any now known or later developed etch stop materials, such as silicon nitride (Si₃N₄), etc. For purposes of clarity, the following description shall refer only to SOI substrate 102. However, the teachings of the disclosure are equally applicable to the etch stop layer embodiment.

Transistor 100 may be formed using any now known or later developed integrated circuit (IC) chip fabrication processes, e.g., photolithography, etc. SOI layer 110 may include but is not limited to silicon, germanium, silicon germanium, silicon carbide, graphene, carbon nanotube, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Buried insulator layer 112 may include but is not limited to: silicon nitride (Si₃N₄), silicon oxide (SiO₂)(typical), fluorinated SiO₂ (FSG), hydrogenated silicon oxycarbide (SiCOH), porous SiCOH, boro-phosho-silicate glass (BPSG), etc. Gate hardmask 108 can be formed using any now known or later developed technique, e.g., depositing a metal such as titanium, nickel, cobalt, etc., annealing to have the metal react with silicon/carbon, and removing unreacted metal.

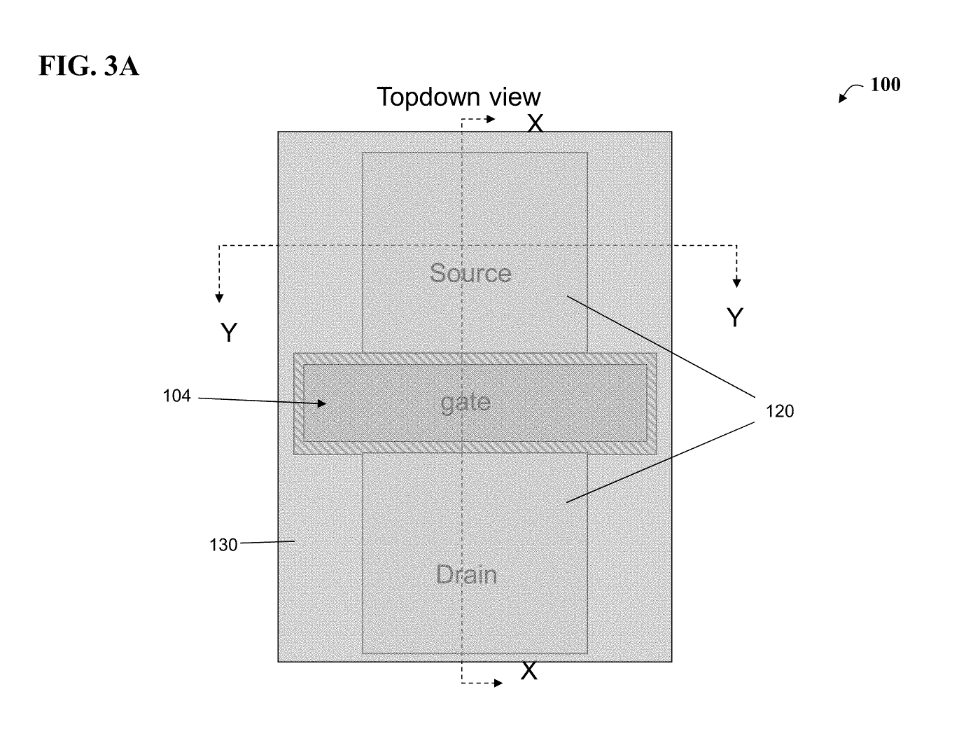

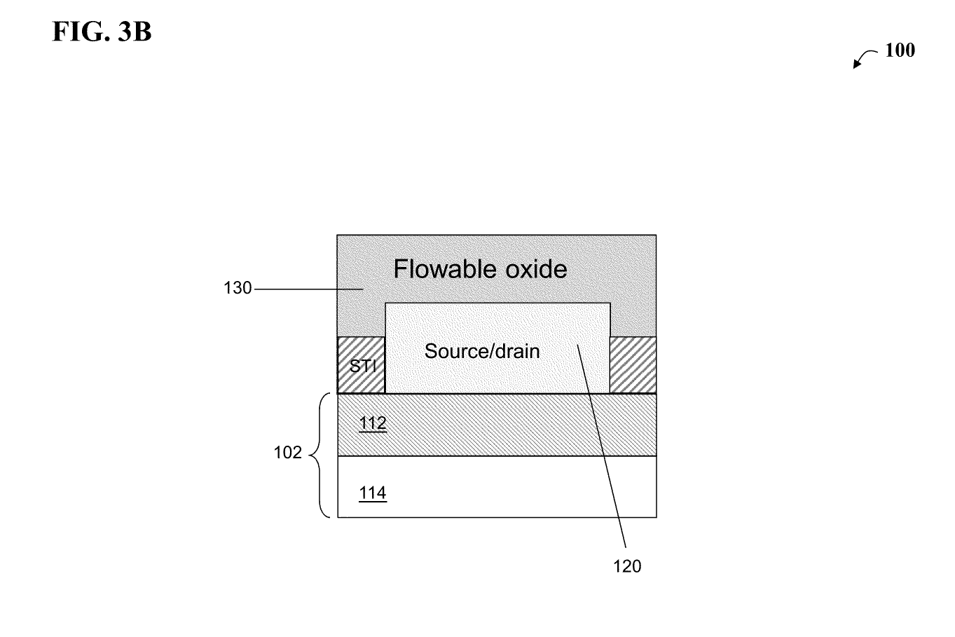

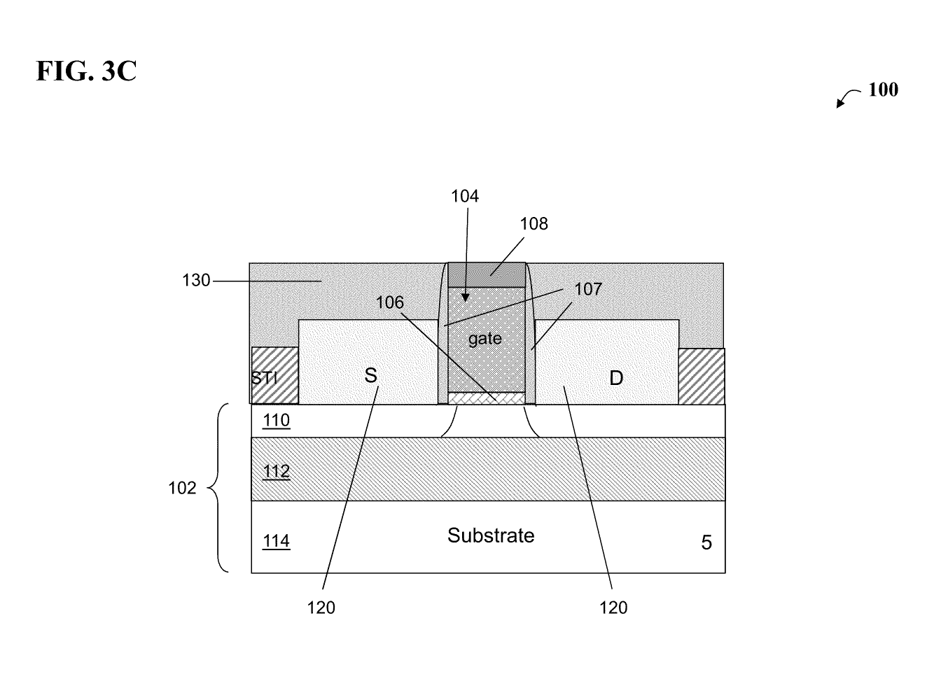

Referring now to FIGS. 3A-C, a depositing of a hardmask 130 over the transistor 100 according to an embodiment is shown. FIG. 3A shows a top-down view of transistor 100 while FIG. 3B shows a Y-Y section view through source/drain region 120 and FIG. 3C shows an X-X section view through the gate 104. As shown, hardmask 130 is formed over transistor 100, i.e., over gate 104, source/drain region 120 and/or spacers 107, if used. Hardmask 130 may include but is not limited to: silicon nitride (Si₃N₄) or silicon nitride compound SiNx, fluorinated SiO₂ (FSG), hydrogenated silicon oxycarbide (SiCOH), porous SiCOH, boro-phosho-silicate glass (BPSG), etc. In one embodiment, hardmask layer 120 is a flowable oxide, such as one including silicon oxide (SiO₂).

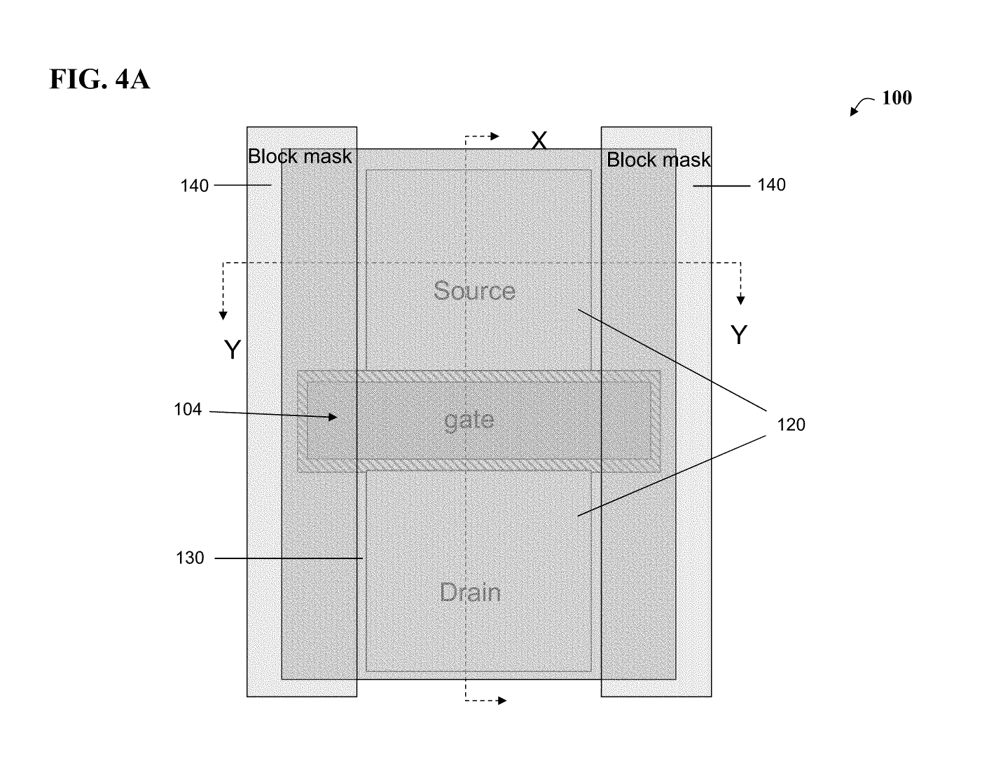

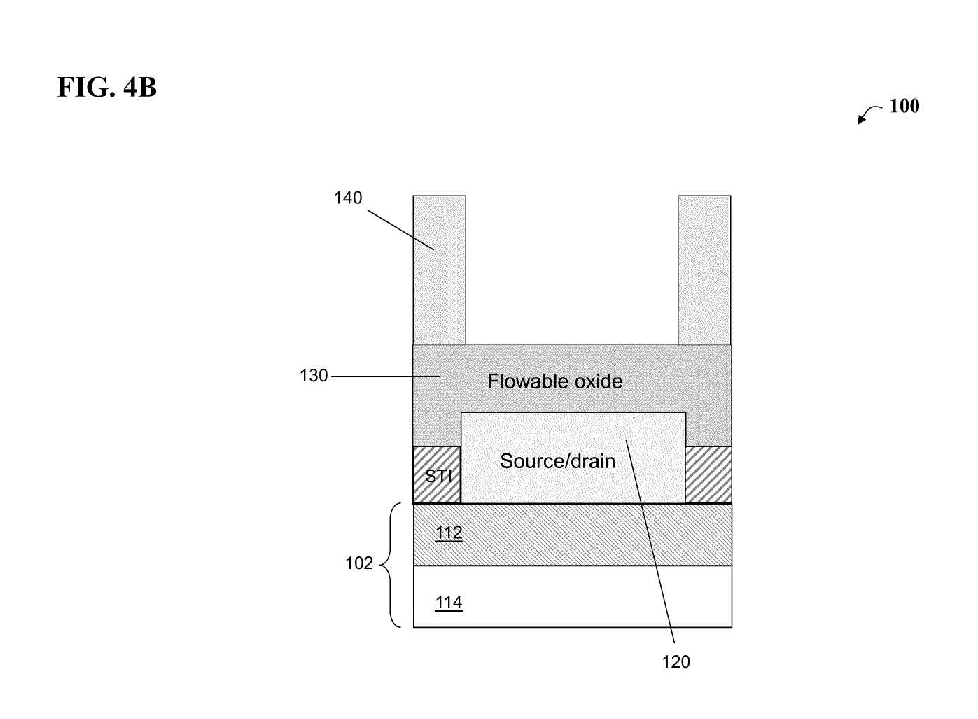

Referring now to FIGS. 4A-B, applying a block mask 140 over transistor 100 according to an embodiment is shown. FIG. 4A shows a top-down view of transistor 100 while FIG. 4B shows a Y-Y section view through source/drain region 120. As shown, block mask 140 is formed over a periphery of transistor 100 and perpendicular to gate 104, such that substantially all or a majority of source/drain region 120, as covered by hardmask 130, remains uncovered by block mask 140. Block mask 140 may include but is not limited to: silicon nitride (Si₃N₄), etc., or any other etch stopping materials now know or later developed. If deemed necessary, a nitride cap surface (not shown) of gate 104 can be treated by oxygen plasma to convert the nitride surface into oxynitride before applying block mask 140.

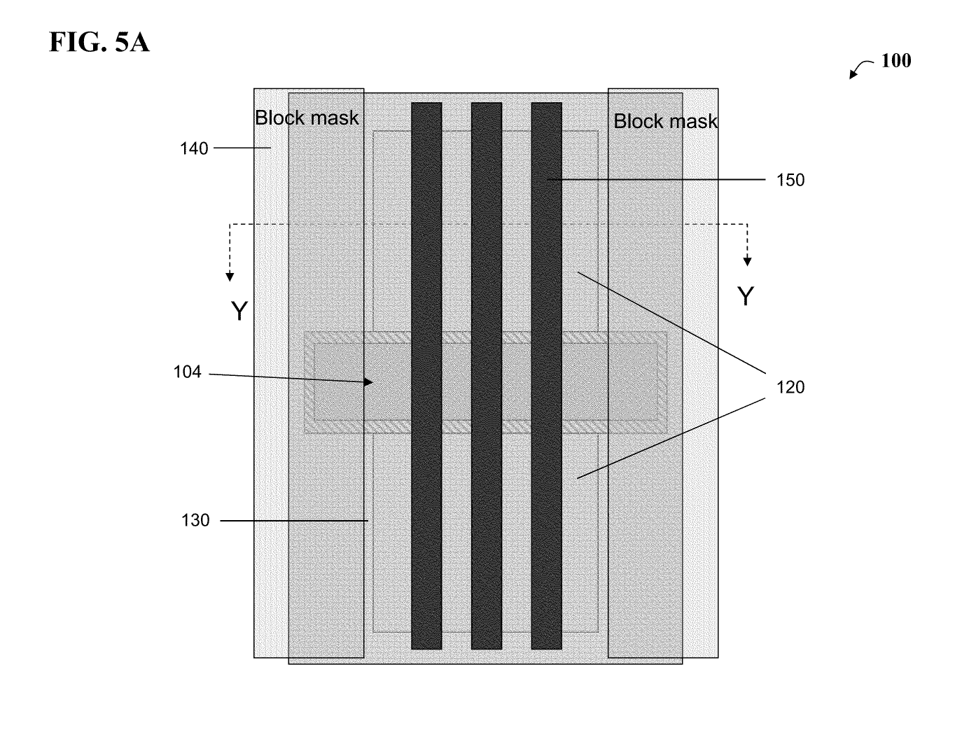

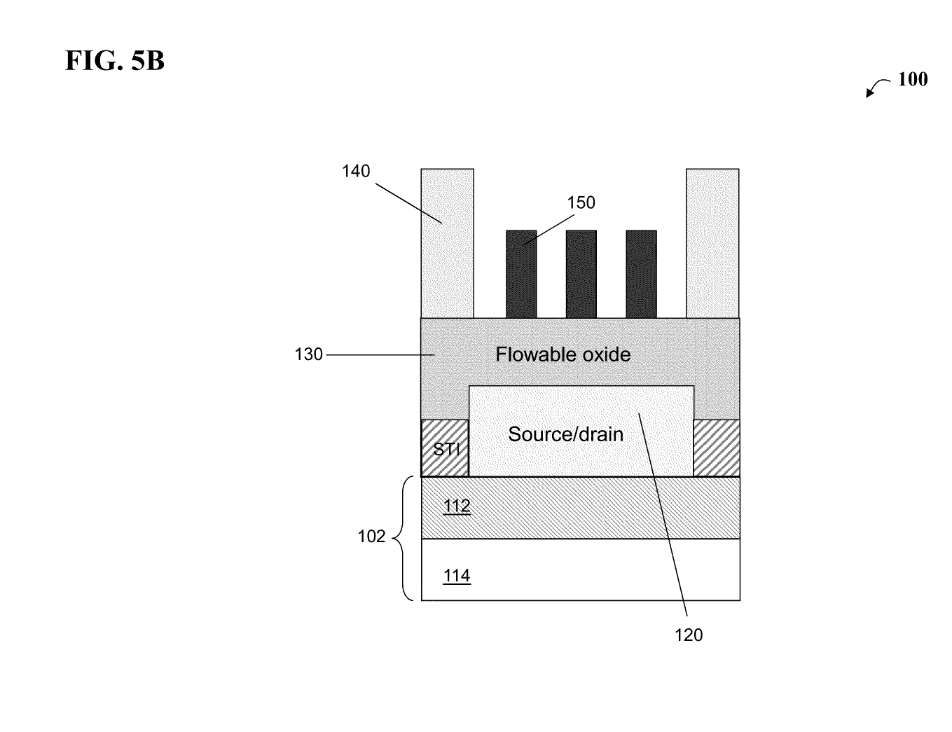

Referring now to FIGS. 5A-B, a directing of a self-assembling polymer 150 according to an embodiment is shown. FIG. 5A shows a top-down view of transistor 100 while FIG. 5B shows a Y-Y section view through source/drain region 120. As shown, polymer 150 self-assembles into desired patterns on the surface of hardmask 130 as directed by block mask 140. Self-assembling polymer 150 may include but is not limited to: a diblock copolymer such as polystyrene (PS): poly(methyl methacrylate) (PMMA), or the like. Such a self-assembling polymer 150 can be applied via spin coating onto hardmask 130. Annealing to have the directed self-assembling polymer 150 interact with the hardmask 130 surface and blockmask 140 trench sidewall surface can then be caused to occur, such as by baking above the polymer glass transition temperature. Such a process would result in an assembling of the self-assembling polymer 150 into aggregates of different micro-phases. Each phase is composed of a chemically distinct block of the polymer structure. The assembling of these phases form patterns. After the pattern formation, one phase can be selectively removed, such as removing PMMA block by an optional UV exposure followed by immersion into an acetic acid developer. After development, patterns formed on hardmask 130 with remaining block of self-assembling polymer 150 alternate with regions in which little or no self-assembling polymer remains.

As illustrated in FIGS. 5A-B, a pattern of relatively linear self-assembling polymer 150 patterns that are aligned parallel to the direction of the gate 104 are shown. It should be realized, however, that different patterns, line widths, and/or distances between self-assembling polymer 150 phases can result from varying such factors as the degree of polymerization of self-assembling polymer 150, the weight ratio of the constituent blocks of self-assembling polymer 150, composition of the underlying hardmask 130, surface chemistry of the underlying hardmask 130 and the sidewall of block mask 140 resulting from different treatments, trenching, and/or the like. Such variations can result in the formation of patterns including, but not limited to: random hole pattern; relatively straight lines running parallel or orthogonal to the direction of gate 104; concentric circle, arc or ellipse; fractal pattern, etc, by self-assembling polymer 150.

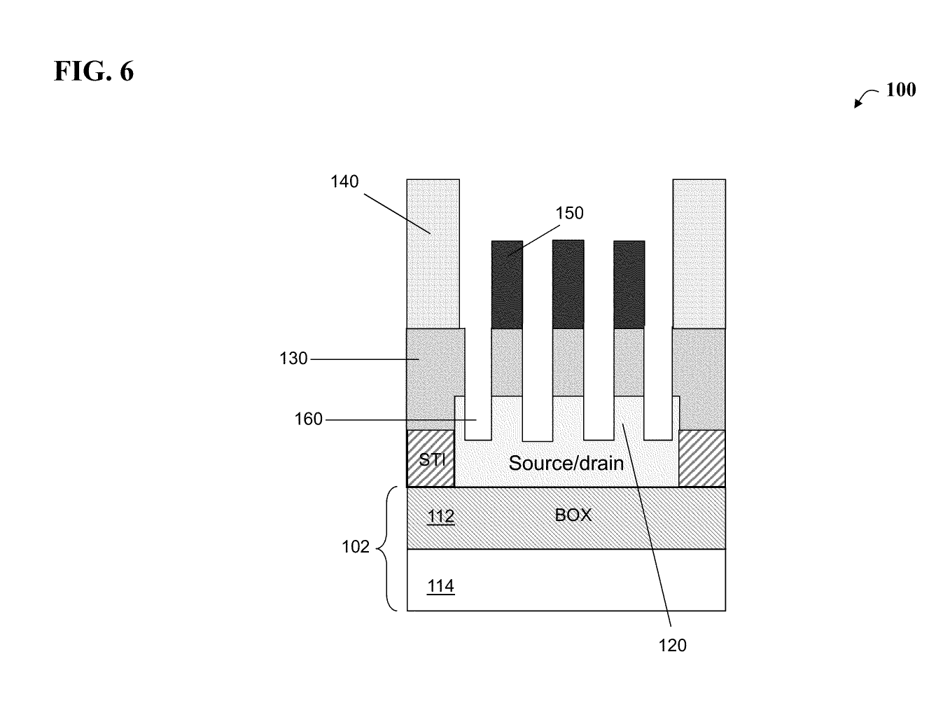

Referring now to FIGS. 6, forming trenches160 into the source/drain region 120 according to an embodiment is shown. Trenches 160 can be formed using an etching process or the like, to form the trenches 160 through the hardmask 130 and into the source/drain region 120. During this process, self-assembling polymer 150 acts as a mask and only the exposed areas of the hardmask 130 and underlying source/drain region 120 are recessed. This results in trenches 160 formed into hardmask 130 and source/drain region 120 matching the pattern of the self-assembling polymer 150 that was directed onto the hardmask 130.

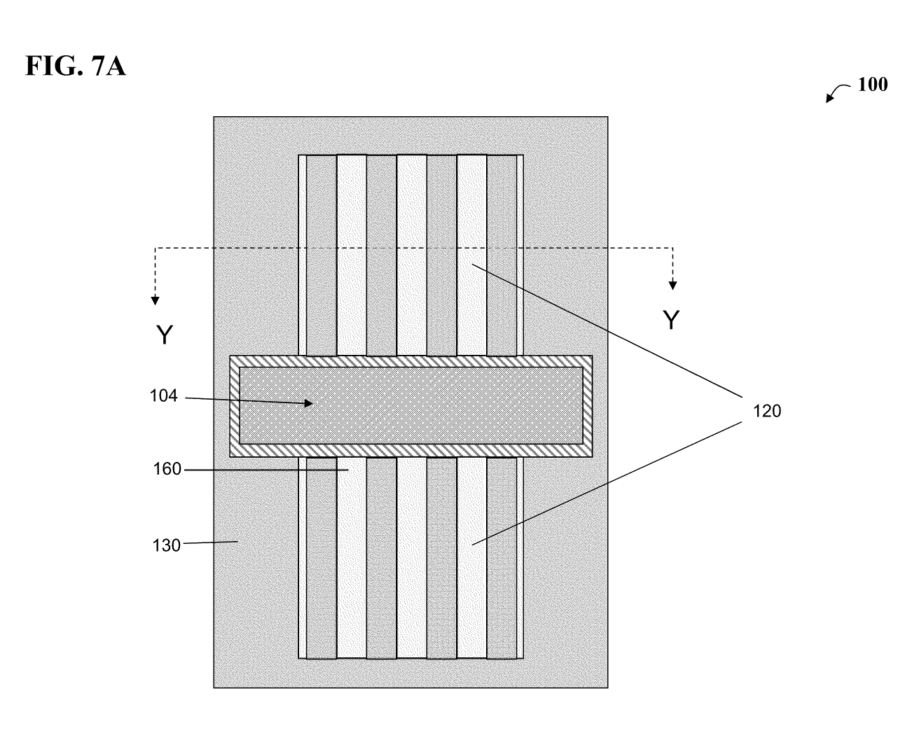

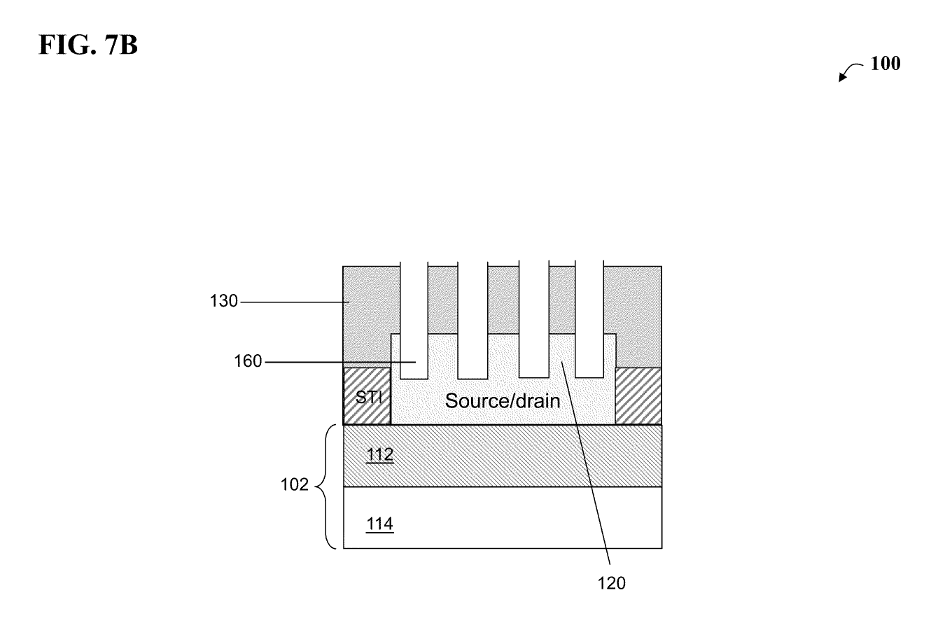

Referring now to FIGS. 7A-B, self-assembling polymer 150 and block mask 140 have been stripped. FIG. 7A shows a top-down view of transistor 100 while FIG. 7B shows a Y-Y section view through source/drain region 120. Stripping can be performed to remove self-assembling polymer 150 and block mask 140, e.g., by one or more reactive ion etches (RIE) or other processes of etching or any other process now known or later discovered to strip layers of these types. What remains is a transistor 100 having a hardmask 130 formed over it and with trenches 160 formed through hardmask 130 and into source/drain region 120.

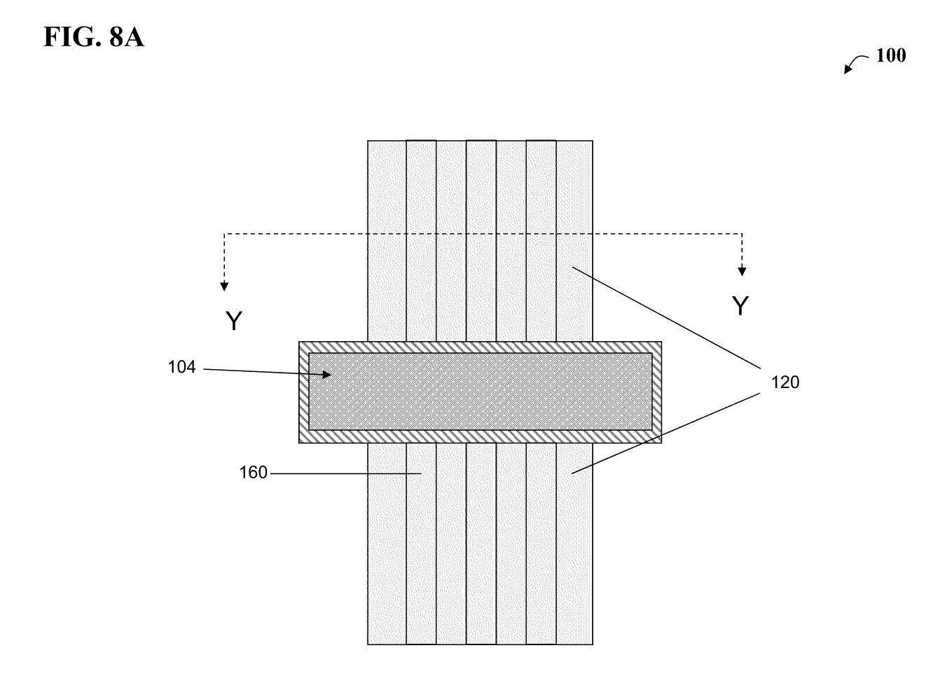

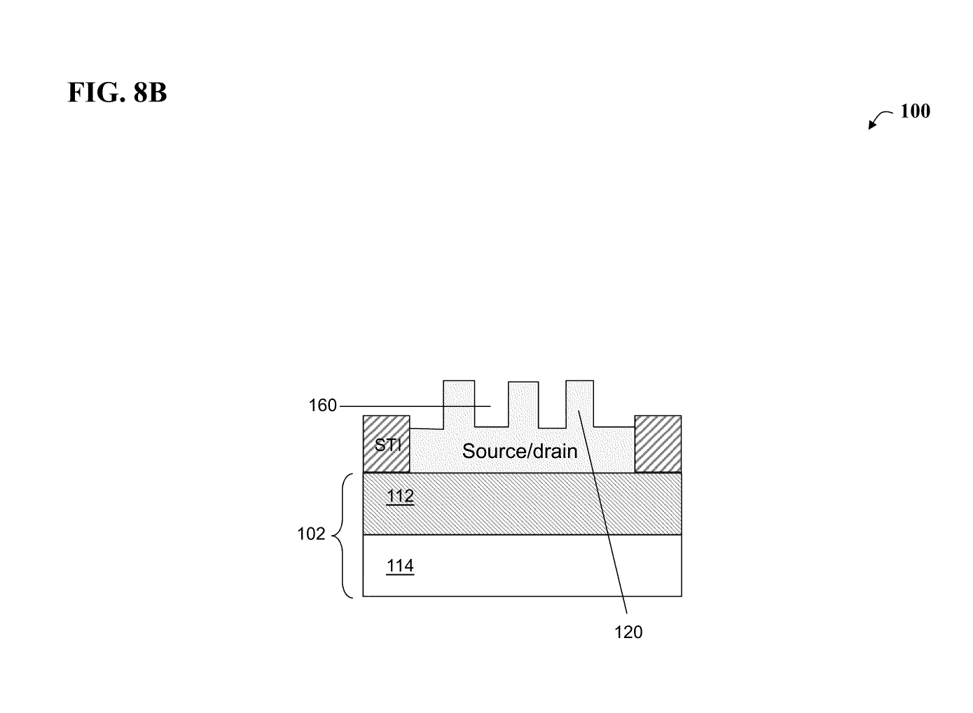

Referring now to FIGS. 8A-B, hardmask 130 has been stripped. FIG. 8A shows a top-down view of transistor 100 while FIG. 8B shows a Y-Y section view through source/drain region 120. Stripping of hardmask 130 can be performed, e.g., using a hafnium (HF) strip with a selectivity of greater than approximately 50:1 HF to hardmask 130 material, or by any other process now known or later discovered to a strip a layer having like composition. What remains is transistor 100 having source/drain region 120 with trenches 160 formed into it in the pattern that was formed by the directed self-assembling polymer 150.

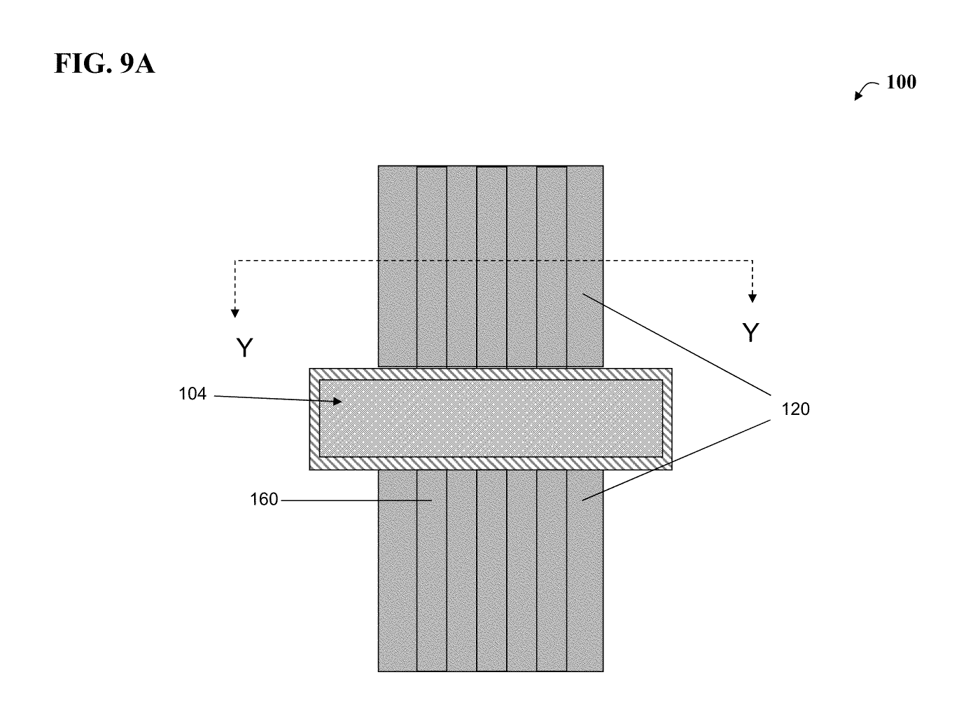

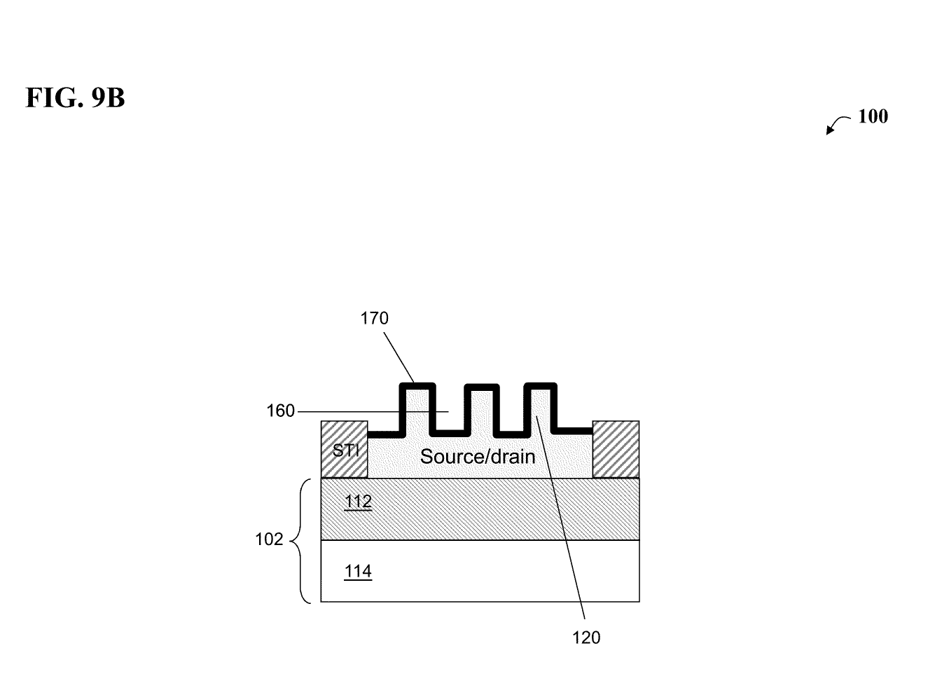

Referring now to FIGS. 9A-B, a forming of a silicide contact 170 according to an embodiment is shown. FIG. 9A shows a top-down view of transistor 100 while FIG. 9B shows a Y-Y section view through source/drain region 120. As shown, silicide contact 170 is formed over transistor 100, i.e., source/drain region 120. Source/drain region 120 maintains the trenches 160 formed into it in the pattern that was formed by the directed self-assembling polymer 150. To this extent, the presence of trenches 160 in source/drain region 120 greatly increases the surface area between silicide contact 170 and source/drain region 120. This increased surface area can help reduce the contact resistance between contact 170 and source/drain region 120 when pitch 30 (FIG. 3) decreases.

The transistor as described above is part of the design for an integrated circuit chip. The chip design is created in a graphical computer programming language, and stored in a computer storage medium (such as a disk, tape, physical hard drive, or virtual hard drive such as in a storage access network). The designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which may include multiple copies of the chip design in question that are to be formed on a wafer. The photolithographic masks are utilized to define areas of the wafer (and/or the layers thereon) to be etched or otherwise processed. The method as described above is also used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

1. A method of forming a source/drain contacts for a transistor, the method comprising:
forming a transistor on a semiconductor-on-insulator (SOI) substrate, the forming including forming a gate and a source/drain region, the SOI substrate including a semiconductor-on-insulator (SOI) layer, a buried insulator layer and a silicon substrate;
forming a hardmask over the transistor;
directing a self-assembling (DSA) polymer to cover a portion of the source/drain region;
forming a series of trenches through the hardmask and into the source/drain region using the DSA polymer as a mask; and
stripping the polymer, and the hardmask.

2. The method of claim 1, further comprising forming a thin silicide layer over the source/drain region, the silicide layer maintaining the series of trenches

3. The method of claim 1, wherein the DSA polymer forms a pattern over the portion of the source/drain region and wherein the series of trenches are formed in the source/drain region having the pattern of the DSA polymer.

4. The method of claim 3, wherein the pattern includes a series of relatively straight parallel trenches that are relatively perpendicular to the gate.

5. The method of claim 1, wherein the series of trenches increase a surface area of the source/drain region.

6. The method of claim 1, wherein the hardmask is a flowable oxide.

7. The method of claim 1, further comprising:
forming a nitride layer over the gate prior to the depositing of the hardmask; and
removing the nitride layer after the trench is formed.

8. The method of claim 1, further comprising:
applying a block mask prior to the directing;
directing the DSA polymer according to the direction of the block mask; and
removing the block mask after the series of trenches is formed.

9. A transistor comprising:
a gate;
a source/drain region coupled to the gate and having a series of channels therein; and
a contact to the source/drain region that extends into the series of channels.

10. The transistor of claim 9, wherein the series of channels forms a series of columns.

11. The transistor of claim 9, wherein the series of channels form a pattern on the source/drain region.

12. The transistor of claim 11, wherein the pattern includes a series of substantially straight parallel trenches that are substantially perpendicular to the gate.

13. A method of forming a contact to a transistor, the method comprising:
forming a transistor on a semiconductor layer positioned over an etch stop layer positioned over a silicon substrate, the forming including forming a gate and a source/drain region;
depositing a hardmask over the integrated circuit;
applying a block mask perpendicular to the gate;
directing a self-assembling (DSA) polymer to cover a portion of the source/drain region in alignment with the block mask;
etching through hardmask and a portion of the source/drain region using the DSA polymer as a mask to form a series of trenches in the source/drain region;
stripping the polymer, the block mask; and the hardmask; and
forming a thin silicide contact layer over the source/drain region the silicide layer maintaining the series of trenches.

14. The transistor of claim 10, wherein each of the series of columns have a width of between approximately 5 nm and approximately 30 nm.

15. The transistor of claim 9, wherein the series of channels has the pattern of a particular masking, self-assembling (DSA) polymer.

16. The transistor of claim 9, wherein the contact includes a silicide layer which maintains the series of channels.

17. The transistor of claim 9, wherein the source/drain region is formed within one of a semiconductor-on-insulator (SOI) substrate and an etch stop layer.
